(19) United States
(12) Patent Application Publication
(10) Pub. No.: US 2017/0194501 A1
(43) Pub. Date: Jul. 6, 2017

(54) ACTIVE DEVICE AND MANUFACTURING METHOD THEREOF

(71) Applicant: Chunghwa Picture Tubes, LTD., Taoyuan City (TW)

(72) Inventors: Chin-Tzu Kao, Changhua County (TW); Ya-Ju Lu, New Taipei City (TW); Jin-Chuan Guo, Taoyuan City (TW)

(21) Appl. No.: 15/054,149

(22) Filed: Feb. 26, 2016

(30) Foreign Application Priority Data
Jan. 6, 2016 (CN) 201610007937.0

(51) Int. Cl. H01L 29/786; H01L 29/423; H01L 21/02; H01L 21/027; H01L 21/4757; H01L 29/24; H01L 29/66

(52) U.S. Cl. CPC H01L 29/7869; H01L 29/24; H01L 29/42356; H01L 29/66969; H01L 21/0273; H01L 21/47573; H01L 21/02565

(57) ABSTRACT

The invention provides an active device and a manufacturing method thereof, the active device disposed on a substrate includes a gate, a gate insulating layer, a metal oxide semiconductor layer, an etch stop layer, a source, and a drain. The gate insulating layer is disposed on the substrate and covers the gate. The metal oxide semiconductor layer is disposed on the gate insulating layer. The etch stop layer is disposed on the metal oxide semiconductor layer. The edges of the metal oxide semiconductor layer are retracted a distance compared to the edges of the etch stop layer. The source and the drain are disposed on the etch stop layer, disposed along the edges of the etch stop layer and the edges of the metal oxide semiconductor layer, and extendedly disposed on the gate insulating layer. A part of the etch stop layer is exposed between the source and the drain.

### CROSS-REFERENCE TO RELATED APPLICATION

This application claims the priority benefit of China application serial no. 201610007937.0, filed on Jan. 6, 2016. The entirety of the above-mentioned patent application is hereby incorporated by reference herein and made a part of this specification.

### BACKGROUND OF THE INVENTION

Field of the Invention

The invention relates to a semiconductor device and a manufacturing method thereof, and more particularly, to an active device and a manufacturing method thereof.

Description of Related Art

In existing metal oxide semiconductor structures, the structure having an etch stop layer is mainly and widely used, and the structure having an etch stop layer is preferred because of device protection ability and because of the stability of device characteristic.

There are two common types of the metal oxide semiconductor structures having an etch stop layer, one is full type ESL metal oxide semiconductor structure, and the other one is non-full type ESL metal oxide semiconductor structure. The full type ESL metal oxide semiconductor structure has a contact window of the source and the drain, so the space of the channel layer is unable to be reduced, so as to affect the aperture ratio of pixels. On the other hand, in the manufacturing process of the non-full type ESL metal oxide semiconductor structure, because the etch stop layer requires a large etching area, the surface of the semiconductor channel layer suffers the dry etching bombardment, so as to affect the contact characteristics of contact window of the source and the drain that are subsequently formed. Furthermore, the etch selectivity between the etch stop layer and the gate insulating layer in the dry etching gas is low, and the short circuit problem between the source and the drain is easily generated because of the gate insulating layer suffering bombardment penetration or being too thin.

### SUMMARY OF THE INVENTION

The invention provides an active device having a preferable efficiency.

The invention also provides a manufacturing method of an active device that is adapted to manufacture the above-mentioned active device.

The active device of the invention is disposed on a substrate and includes a gate, a gate insulating layer, a metal oxide semiconductor layer, an etch stop layer, a source, and a drain. The gate insulating layer is disposed on the substrate and covers the gate. The metal oxide semiconductor layer is disposed on the gate insulating layer. The etch stop layer is disposed on the metal oxide semiconductor layer, wherein the edges of the metal oxide semiconductor layer are retracted a distance compared to the edges of the etch stop layer. The source and the drain are disposed on the etch stop layer, disposed along the edges of the etch stop layer and the edges of the metal oxide semiconductor layer, and extendedly disposed on the gate insulating layer, wherein a part of the etch stop layer is exposed between the source and the drain.

In one embodiment of the invention, the material of the metal oxide semiconductor layer includes indium gallium zinc oxide, indium zinc oxide, zinc indium tin oxide, or zinc tin oxide.

In one embodiment of the invention, the source and the drain are in direct contact with the edges of the metal oxide semiconductor layer.

A manufacturing method of an active device of the invention includes following steps. A gate is formed on a substrate. A gate insulating layer is formed on the substrate, wherein the gate insulating layer covers the gate. A metal oxide semiconductor material layer is formed on the gate insulating layer. An etch stop material layer is formed on the metal oxide semiconductor material layer. A patterned photoresist layer is formed on the etch stop material layer. An etch stop layer is formed by using the patterned photoresist layer as a first mask to perform dry etching process on the etch stop material layer. The patterned photoresist layer is removed to expose the etch stop layer. A metal oxide semiconductor layer is formed by using the etch stop layer as a second mask to perform wet etching process on the metal oxide semiconductor material layer. The edges of the metal oxide semiconductor layer are retracted a distance compared to the edges of the etch stop layer. A source and a drain are formed on the etch stop layer, wherein the source and the drain are disposed along the edges of the etch stop layer and the edges of the metal oxide semiconductor layer and extendedly disposed on the gate insulating layer, and a part of the etch stop layer is exposed between the source and the drain.

In one embodiment of the invention, the material of the metal oxide semiconductor material layer includes indium gallium zinc oxide, indium zinc oxide, zinc indium tin oxide, or zinc tin oxide.

In one embodiment of the invention, the source and the drain are in direct contact with the edges of the metal oxide semiconductor layer.

Based on the above, in the invention, the metal oxide semiconductor layer is formed by using the etch stop layer as masks to perform wet etching process on the metal oxide semiconductor material layer, or by using the patterned photoresist layer and the etch stop layer as masks to perform the etching process and then remove the patterned photoresist layer. Therefore, the edges of the metal oxide semiconductor layer, which is formed, are retracted a distance compared to the edges of the etch stop layer. As a result, the length of the metal oxide semiconductor layer is shortened, the conductive capability of the active device in the invention may be effectively improved, and the aperture ratio of pixels may be effectively increased in subsequent application of the active device, so as to increase the display resolution. Furthermore, when the etch stop layer is formed by performing dry etching process on the etch stop material layer, because the etch selectivity between the etch stop material layer and the metal oxide semiconductor material layer is extremely high, the metal oxide semiconductor material layer may serve as a resist layer to effectively prevent the gate insulating layer from being etched. In addition, because the metal oxide semiconductor layer and the etch stop layer are defined by the same mask, the self-alignment between the metal oxide semiconductor layer and the etch stop layer is not shifted and the number of used masks can be reduced so as to reduce productions cost.

To make the above features and advantages of the invention more comprehensible, embodiments accompanied with drawings are described in detail as follows.

### BRIEF DESCRIPTION OF THE DRAWINGS

FIG. 1A to FIG. 1G are schematic cross-sectional views of a manufacturing method of an active device of an embodiment of the invention.

### DESCRIPTION OF THE EMBODIMENTS

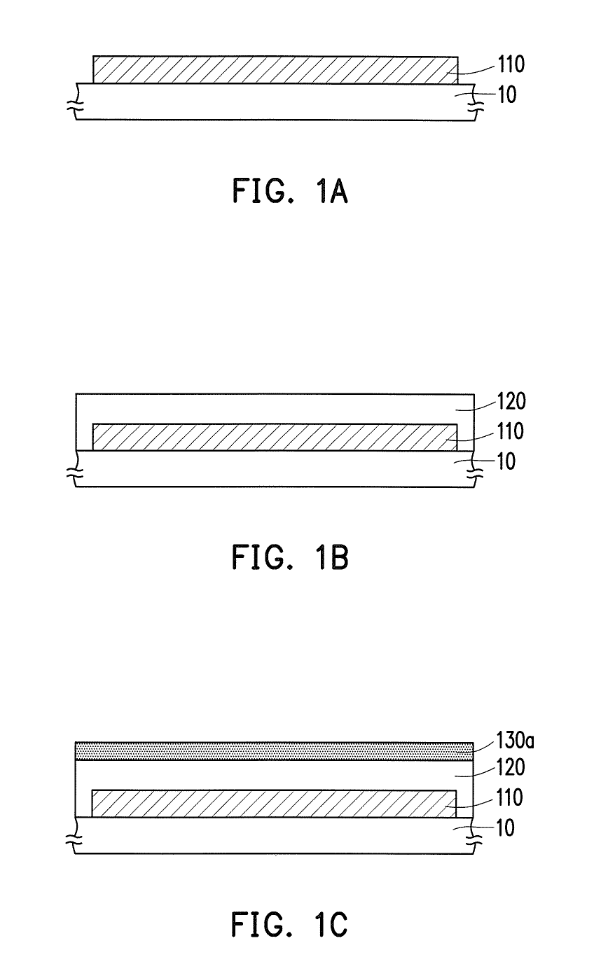

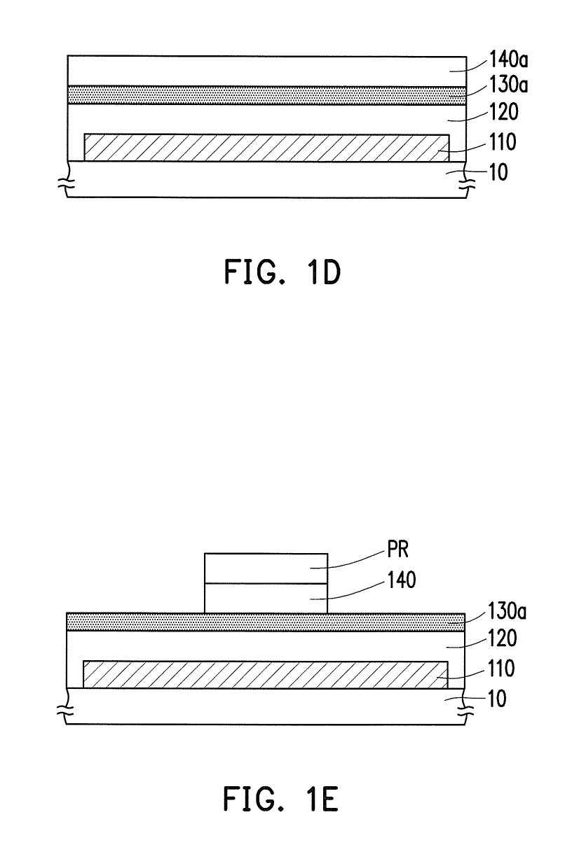

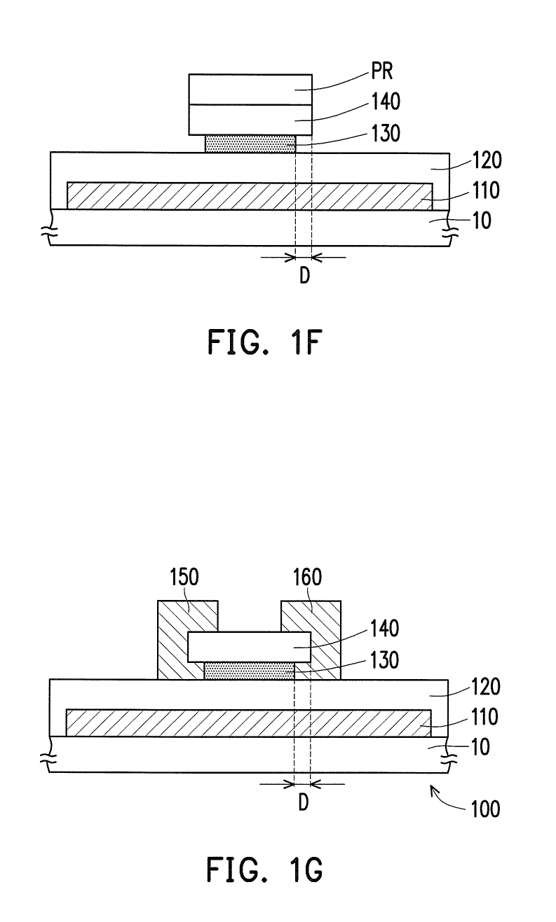

Referring to FIG. 1A, regarding a manufacturing method of an active device in the present embodiment, firstly, a gate 110 is formed on a substrate 10. Herein, the substrate 10 is, for example, a glass substrate, a metal substrate, or a plastic substrate; and, the material of the gate 110 is, for instance, a metal, such as molybdenum, aluminum, copper, titanium, silver, etc., or a metal alloy, such as tantalum molybdenum alloy, molybdenum niobium alloy, aluminum neodymium alloy, etc., or a multilayer metal structure.

Next, referring to FIG. 1B, a gate insulating layer 120 is formed on the substrate 10, wherein the gate insulating layer 120 covers the gate 110. Herein, the gate insulating layer 120 completely covers the peripheral surfaces of the gate 110, wherein the material of the gate insulating layer 120 is silicon nitride, silicon oxide, or aluminium oxide, for example.

Subsequently, referring to FIG. 1C, a metal oxide semiconductor material layer 130a is formed on the gate insulating layer 120. Herein, the metal oxide semiconductor material layer 130a completely covers the top surface of the gate insulating layer 120, wherein the material of the metal oxide semiconductor material layer 130a includes indium gallium zinc oxide, indium zinc oxide, zinc indium tin oxide, or zinc tin oxide.

Next, referring to FIG. 1D, an etch stop material layer 140a is formed on the metal oxide semiconductor material layer 130a. Herein, the etch stop material layer 140a completely covers the top surface of the metal oxide semiconductor material layer 130a, wherein the material of the etch stop material layer 140a is, silicon oxide, silicon nitride, or aluminium oxide, for example.

After that, referring to FIG. 1D and FIG. 1E simultaneously, a patterned photoresist layer PR is formed on the etch stop material layer 140a. Subsequently, an etch stop layer 140 is formed by using the patterned photoresist layer PR as a first mask to perform dry etching process on the etch stop material layer 140a. Herein, the gas used in dry etching process is carbon tetrafluoride (CF4) or sulfur hexafluoride (SF6). Furthermore, because the etch selectivity between the etch stop material layer 140a and the metal oxide semiconductor material layer 130a is extremely high, the metal oxide semiconductor material layer 130a may serve as a resist layer to effectively prevent the gate insulating layer 120 from being etched.

After that, referring to FIG. 1E and FIG. 1F simultaneously, the patterned photoresist layer PR is removed to expose the etch stop layer 140. Next, a metal oxide semiconductor layer 130 is formed by using the etch stop layer 140 as a second mask to perform wet etching process on the metal oxide semiconductor material layer 130a. Herein, the etching solution used in the wet etching process is oxalic acid. On the other hand, the metal oxide semiconductor layer 130 can also be formed by using the patterned photoresist layer PR and the etch stop layer 140 as masks to perform the etching process and then remove the patterned photoresist layer PR. Because the wet etching process is adopted to form the metal oxide semiconductor layer 130 in the present embodiment, the metal oxide semiconductor material layer 130a is laterally etched in the wet etching process, and therefore, the edges of the metal oxide semiconductor layer 130, which is formed, are retracted a distance D compared to the edges of the etch stop layer 140. As a result, the length of the metal oxide semiconductor layer 130 is shortened, so as to effectively improve the conductive capability of the product. In addition, because the metal oxide semiconductor layer 130 and the etch stop layer 140 are defined by the same mask, the self-alignment between the metal oxide semiconductor layer 130 and the etch stop layer 140 is not shifted and the number of used masks can be reduced so as to reduce production cost.

Finally, referring to FIG. 1G, a source 150 and a drain 160 are formed on the etch stop layer 140, wherein the source 150 and the drain 160 are disposed along the edges of the etch stop layer 140 and the edges of the metal oxide semiconductor layer 130 and extendedly disposed on the gate insulating layer 120, and a part of the etch stop layer 140 is exposed between the source 150 and the drain 160. Herein, the source 150 and the drain 160 are in direct contact with the edges of the metal oxide semiconductor layer 130 to form a channel. The materials of the source 150 and the drain 160 are, for instance, a metal, such as molybdenum, aluminum, copper, titanium, silver, etc., or a metal alloy, such as tantalum molybdenum alloy, molybdenum niobium alloy, aluminum neodymium alloy, etc., or a multilayer metal structure. Thereby, the active device 100 is completely manufactured.

Structurally, referring to FIG. 1G, the active device 100 is disposed on the substrate 10 and includes the gate 110, the gate insulating layer 120, the metal oxide semiconductor layer 130, the etch stop layer 140, the source 150, and the drain 160. The gate insulating layer 120 is disposed on the substrate 10 and covers the gate 110. The metal oxide semiconductor layer 130 is disposed on the gate insulating layer 120. The etch stop layer 140 is disposed on the metal oxide semiconductor layer 130, wherein the edges of the metal oxide semiconductor layer 130 are retracted a distance D compared to the edges of the etch stop layer 140, and the thickness of the etch stop layer 140 is greater than the thickness of the metal oxide semiconductor layer 130. The source 150 and the drain 160 are disposed on the etch stop layer 140, disposed along the edges of the etch stop layer 140 and the edges of the metal oxide semiconductor layer 130, and extendedly disposed on the gate insulating layer 120, wherein a part of the etch stop layer 140 is exposed between the source 150 and the drain 160. The source 150 and the drain 160 are in direct contact with the edges of the metal oxide semiconductor layer 130 to form a channel.

Because the edges of the metal oxide semiconductor layer 130 in the present embodiment are retracted a distance D compared to edges of the etch stop layer 140, the source 150 and the drain 160 are in direct contact with the edges of the metal oxide semiconductor layer 130 to form a channel. Therefore, the length of the metal oxide semiconductor layer 130 is shortened, the conductive capability of the active device 100 of the present embodiment may be effectively improved, and the aperture ratio of pixels may be effectively increased in subsequent application to the display panel, so as to increase the display resolution.

In summary, the metal oxide semiconductor layer is formed by using the etch stop layer as masks to perform wet etching process on the metal oxide semiconductor material layer in the invention, or by using the patterned photoresist layer and the etch stop layer as masks to perform the etching process and then remove the patterned photoresist layer. Therefore, the edges of the metal oxide semiconductor layer, which is formed, are retracted a distance compared to the edges of the etch stop layer. As a result, the length of the metal oxide semiconductor layer is shortened, the conductive capability of the active device in the invention may be effectively improved, and the aperture ratio of pixels may be effectively increased in subsequent application of the active device, so as to increase the display resolution. Furthermore, when the etch stop layer is formed by performing dry etching process on the etch stop material layer, because the etch selectivity between the etch stop material layer and the metal oxide semiconductor material layer is extremely high, the metal oxide semiconductor material layer may serve as a resist layer to effectively prevent the gate insulating layer from being etched. In addition, because the metal oxide semiconductor layer and the etch stop layer are defined by the same mask, the self-alignment between the metal oxide semiconductor layer and the etch stop layer is not shifted and the number of used masks can be reduced so as to reduce productions cost.

1. An active device, disposed on a substrate, and the active device comprising:
a gate;
a gate insulating layer, disposed on the substrate and covering the gate;
a metal oxide semiconductor layer, disposed on the gate insulating layer;
an etch stop layer, disposed on the metal oxide semiconductor layer, wherein edges of the metal oxide semiconductor layer are retracted a distance compared to edges of the etch stop layer; and
a source and a drain, disposed on the etch stop layer, disposed along the edges of the etch stop layer and the edges of the metal oxide semiconductor layer, and extendedly disposed on the gate insulating layer, wherein a part of the etch stop layer is exposed between the source and the drain.

2. The active device as recited in claim 1, wherein a material of the metal oxide semiconductor layer comprises indium gallium zinc oxide, indium zinc oxide, zinc indium tin oxide, or zinc tin oxide.

3. The active device as recited in claim 1, wherein the source and the drain are in direct contact with the edges of the metal oxide semiconductor layer.

4. A method of manufacturing an active device, including following steps:
forming a gate on a substrate;
forming a gate insulating layer on the substrate, wherein the gate insulating layer covers the gate;
forming a metal oxide semiconductor material layer on the gate insulating layer;
forming an etch stop material layer on the metal oxide semiconductor material layer;
forming a patterned photoresist layer on the etch stop material layer;
fonning an etch stop layer by using the patterned photoresist layer as a first mask to perform dry etching process on the etch stop material layer;
removing the patterned photoresist layer to expose the etch stop layer;
forming a metal oxide semiconductor layer by using the etch stop layer as a second mask to perform wet etching process on the metal oxide semiconductor material layer, wherein edges of the metal oxide semiconductor layer are retracted a distance compared to edges of the etch stop layer; and
forming a source and a drain on the etch stop layer, wherein the source and the drain are disposed along the edges of the etch stop layer and the edges of the metal oxide semiconductor layer and extendedly disposed on the gate insulating layer, and a part of the etch stop layer is exposed between the source and the drain.

5. The method of claim 4, wherein a material of the metal oxide semiconductor material layer comprises indium gallium zinc oxide, indium zinc oxide, zinc indium tin oxide, or zinc tin oxide.

6. The method of claim 4, wherein the source and the drain are in direct contact with the edges of the metal oxide semiconductor layer.
